(19) United States
(12) Patent Application Publication
(10) Pub. No.: US 2009/0091021 A1
(43) Pub. Date: Apr. 9, 2009

(54) SEMICONDUCTOR DEVICE AND METHOD OF MANUFACTURING THE SAME

(75) Inventor: Yoshifumi Nakamura, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/211,364

(22) Filed: Sep. 16, 2008

(30) Foreign Application Priority Data
Oct. 3, 2007 (JP) 2007-259296
Apr. 4, 2008 (JP) 2008-097648

(51) Int. Cl. H01L 21/56; H01L 23/36

(52) U.S. Cl. 257/707; 438/122; 257/E21.502; 257/E23.101

(57) ABSTRACT

An insulating resin 4 is packed between a semiconductor chip 5 and a tape carrier 1, with taper portions 4a formed on the side faces, and a resin layer 7 is formed in close contact with the rear face of the semiconductor chip 5, the tape carrier 1, and the taper portions 4a; further, by forming a metal layer 9 having a depression 8 and formed with a shape enabling close contact with the resin layer 7, the metal layer 9, which functions as a heat spreader, can be fastened stably to the semiconductor chip 5, and moreover heat generated from the semiconductor chip 5 is transmitted efficiently not only from the rear face of the semiconductor chip 5 but from the side faces thereof to the metal layer 9 for heat dissipation, whereby heat dissipation can be improved.

### FIELD OF THE INVENTION

The present invention relates to a semiconductor device configured on a flexible insulating base material on which is provided conductive wiring, such as a tape wiring substrate; a manufacturing method for such a device; and a mounted member using such a device.

### BACKGROUND OF THE INVENTION

Tape Carrier Package (TCP) and Chip On Film (COF) are known as types of package modules which use a tape wiring substrate. TCP and COF have a structure in which semiconductor chips are mounted on a flexible insulating tape wiring substrate, and are molded with a resin to protect mounted portions thereof. The tape wiring substrate comprises, as the main elements, an insulating film base material and a plurality of conductive wires formed on the surface thereof. As the film base material, polyimides are generally used; and as the conductive wires, copper is used. Layers of a metal plated film and a solder resist, which is an insulating resin, are formed on the conductive wires as necessary.

A principal application of TCP and COF is in mounting drivers for driving display panels, such as liquid crystal panels. In this case, the conductive wires on the tape wiring substrate are divided and arranged into a first group that forms external terminals for output signals, and a second group that forms external terminals for input signals; and semiconductor devices are mounted between the two groups of conductive wires. Inner leads, which are end portions for connection with the semiconductor chips in the conductive wires on the tape wiring substrate, are connected to electrode pads on the semiconductor chips via protruding electrodes. Outer lead bonding portions which form the external terminals for output signals in one of the groups of conductive wires are connected to electrodes formed on the peripheral portion of the display panel; and outer lead bonding portions which form the external terminals for input signals in the other one of the groups of conductive wires are connected to terminals on a motherboard.

Moreover, TCP and COF are often fixed to a housing of a product, such as an LCD.

One example of the above-described semiconductor devices is explained referring to FIG. 12. FIG. 12 is a cross-sectional view showing the structure of a semiconductor device of the prior art, and is a cross-sectional view showing the principal region comprising a semiconductor chip mounting portion on a tape carrier.

In FIG. 12, 1 indicates a portion of a flexible and insulating tape carrier; on the tape carrier 1 are formed conductive wires 2; 5 is a semiconductor chip; and 5a is a protruding portion formed on the semiconductor chip 5. The surface of the semiconductor chip 5 is bonded to the conductive wires 2 of the tape carrier 1 via protruding electrodes 6. Also, the surface and side faces of the semiconductor chip 5 are molded by an insulating resin 4. Also, a heat-dissipating heat spreader 17 is installed with adhesive 16 on the rear face of the semiconductor chip 5.

In a heat-dissipating resin-molded semiconductor device of the prior art, adhesion between the rear face of the semiconductor chip 5 and the heat spreader 17 has been uneven due to wraparound of the insulating resin 4; however, a configuration has been employed, in which the protruding portion 5a is provided on the side faces of the semiconductor chip 5 to prevent wraparound of the insulating resin 4, and after molding of the semiconductor chip 5 with the insulating resin 4, the heat spreader 17 is bonded to the rear face of the semiconductor chip 5, whereby heat dissipation is secured, while avoiding breakage of the semiconductor chip 5.

In the semiconductor device with the above configuration, because a heat spreader for dissipating heat is formed only on the rear face of the semiconductor chip, installation of the heat spreader is affected by the state of the rear face of the semiconductor chip, and thereby efficient installation has been hindered. Further, because connection with the heat spreader has been only at the rear face of the semiconductor chip, heat dissipation efficacy has not been sufficient.

### DISCLOSURE OF THE INVENTION

The present invention has been devised in light of the above problems, and has an object of stably fastening a heat spreader of a metal layer and a semiconductor chip, and moreover heightening the heat dissipation from the semiconductor chip.

In order to attain the above object, a semiconductor device of this invention, in which a semiconductor chip is mounted on a tape carrier, comprises: an insulating resin, packed into a gap between the tape carrier and the semiconductor chip, and forming a taper portion on side faces; a resin layer, formed so as to be in contact with the rear face of the semiconductor chip and with at least a portion of the tape carrier as well as with the taper portion, and having higher thermal conductivity than the insulating resin; and a metal layer, comprising a depression with a shape corresponding to the semiconductor chip and the insulating resin layer on the taper portion, and formed so as to be in close contact with the resin layer.

Further, a semiconductor device, in which a semiconductor chip is mounted on a tape carrier, comprises: an insulating resin packed so as to cover the surface of the semiconductor chip and forming a taper portion on side faces, with a hole formed in the tape carrier in a region opposing the semiconductor chip; a resin layer, formed so as to be in contact with the rear face of the semiconductor chip and at least a portion of the tape carrier, as well as the taper portion, and having higher thermal conductivity than the insulating resin; and, a metal layer, comprising a depression with a shape corresponding to the semiconductor chip and the insulating resin layer on the taper portion, and formed so as to be in close contact with the resin layer.

Further, the metal layer is a sheet-shaped metal layer formed corresponding to the shape of the resin layer.

Further, one or a plurality of holes are formed in a portion of the metal layer in a region above the semiconductor chip.

Further, a cutout is provided on the surface of the metal layer opposite that in which the depression is formed.

Further, a second metal layer is provided on the rear face of the tape carrier.

Further, the region of the second metal layer opposing the semiconductor chip protrudes in the direction of the tape carrier.

Further, a second resin layer is provided on the rear face of the tape carrier.

Further, a housing comprising a protruding portion on the rear face of the second resin layer is provided, the region of the housing opposing the semiconductor chip protruding in the direction of the tape carrier.

Further, the metal layer, the tape carrier, and the second metal layer are fixed by a screw or rivet.

Further, the metal layer, the tape carrier, and the second resin layer are fixed by a screw or rivet.

Further, a screw or rivet penetrates the tape carrier and the metal layer.

Further, a third metal layer is formed on the rear face of the tape carrier, and a screw or rivet penetrates the third metal layer, the tape carrier, and the metal layer.

Further, the screw or rivet is provided within 50 mm from the semiconductor chip.

Further, a conductive filler is intermixed in the resin layer.

Further, the resin layer has a metal filler with a low melting point.

Further, the resin layer comprises a thermoplastic resin.

Also, a method of manufacturing a semiconductor device of this invention comprises the steps of: mounting a semiconductor chip on a tape carrier, and positioning a plurality of electrode pads formed on the surface of the semiconductor chip and a plurality of conductive wires formed on the tape carrier to correspond to the electrode pads and connecting the plurality of electrode pads to the plurality of conductive wires via protruding electrodes; packing a gap between the tape carrier and the semiconductor chip with an insulating resin, so as to form a taper portion on the side faces; forming a resin layer, having higher thermal conductivity than the insulating resin layer, so as to be in contact with the rear face of the semiconductor chip and at least a portion of the tape carrier as well as the taper portion; and fastening a metal layer having a depression with a shape corresponding to the semiconductor chip and to the insulating resin layer on the taper portion, so as to be in close contact with the resin layer.

Further, one or a plurality of holes are formed in a portion of the metal layer on the semiconductor chip.

Further, after the process of fastening the metal layer, heating is performed to allow the metal layer to be in closer contact.

### BRIEF DESCRIPTION OF THE DRAWINGS

FIG. 1 is a cross-sectional view showing the structure of a semiconductor device of Embodiment 1;

FIG. 2A is a process cross-sectional view of a method of manufacturing the semiconductor device of Embodiment 1;

FIG. 2B is a process cross-sectional view of the method of manufacturing the semiconductor device of Embodiment 1;

FIG. 2C is a process cross-sectional view of the method of manufacturing the semiconductor device of Embodiment 1;

FIG. 2D is a process cross-sectional view of the method of manufacturing the semiconductor device of Embodiment 1;

FIG. 3 is a cross-sectional view showing the structure of the mounted semiconductor device in Embodiment 1;

FIG. 4 is a cross-sectional view showing the structure of a semiconductor device of Embodiment 2;

FIG. 5A is a process cross-sectional view of a method of manufacturing the semiconductor device of Embodiment 2;

FIG. 5B is a process cross-sectional view of the method of manufacturing the semiconductor device of Embodiment 2;

FIG. 5C is a process cross-sectional view of the method of manufacturing the semiconductor device of Embodiment 2;

FIG. 5D is a process cross-sectional view of the method of manufacturing the semiconductor device of Embodiment 2;

FIG. 6 is a cross-sectional view showing the structure of a semiconductor device of Embodiment 3;

FIG. 7 is a cross-sectional view showing another structure of the semiconductor device of Embodiment 2;

FIG. 8 is a cross-sectional view showing the structure of a semiconductor device of Embodiment 4;

FIG. 9 is a cross-sectional view showing the structure of a semiconductor device of Embodiment 5;

FIG. 10 is a cross-sectional view showing the structure of a mounted semiconductor device of Embodiment 6;

FIG. 11 is a cross-sectional view showing another structure of the mounted semiconductor device of Embodiment 6; and,

FIG. 12 is a cross-sectional view showing the structure of a semiconductor device of the prior art.

### DESCRIPTION OF THE EMBODIMENTS

Below, embodiments of the present invention are explained in detail, referring to the drawings.

### Embodiment 1

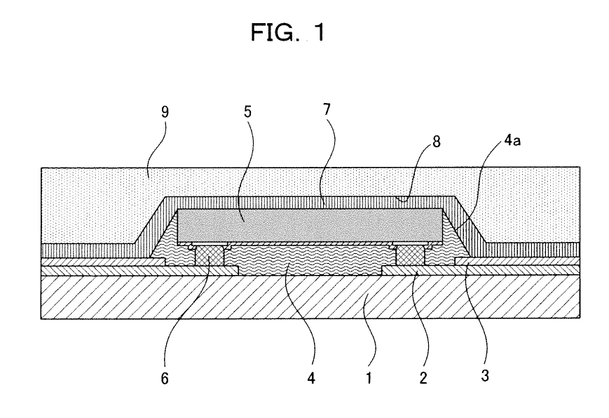

FIG. 1 is a cross-sectional view showing the structure of a semiconductor device of Embodiment 1.

In FIG. 1, conductive wires 2 are provided on a tape carrier 1, and the end portions of the taper carrier form inner leads. Each inner lead is joined to an electrode pad positioned on a semiconductor chip 5, with a protruding electrode 6 intervening. Further, solder resist 3 is formed so as to cover a portion of the conductive wires 2.

Here, an insulating resin 4 is packed between the tape carrier 1 and the semiconductor chip 5 in order to protect the surface of the semiconductor chip 5. This insulating resin 4 is also formed at a portion of the side-face portions of the semiconductor chip 5, to form a taper portion 4a.

Further, a resin layer 7, with thermal conductivity higher than that of the insulating resin 4, is formed to be in close contact with the rear face of the semiconductor chip, the taper portion 4a of the insulating resin 4, and at least a portion of the tape carrier 1 comprising the solder resist 3.

Further, a metal layer 9, having a depression 8 corresponding to the semiconductor chip 5 and the taper portion 4a of the insulating resin layer 4, is formed in close contact on the resin layer 7.

In this way, by forming the metal layer 9, formed on the semiconductor chip 5 and the taper portion 4a of the insulating resin layer 4, and formed with a shape to make close contact with the resin layer 7, the metal layer 9, functioning as a heat spreader, and the semiconductor chip 5 can be fastened with stability, whereby heat can be transmitted efficiently and stably from the rear face and side faces of the semiconductor chip 5 to the metal layer 9, which has excellent thermal conductivity.

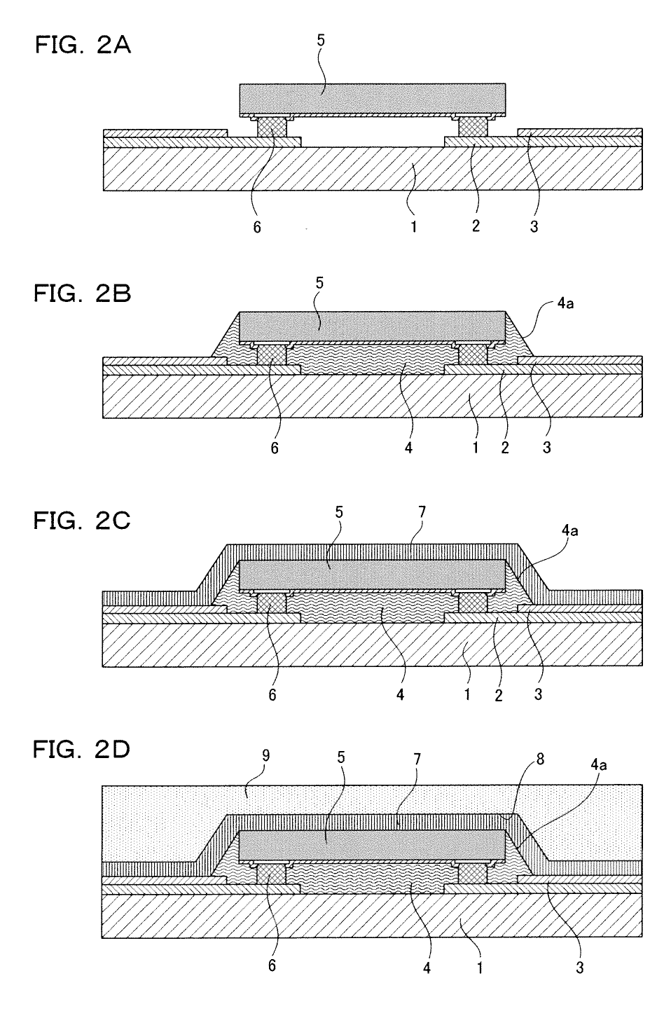

Next, a method of manufacturing the semiconductor device of Embodiment 1 is explained using FIG. 2A to FIG. 2D.

FIG. 2A to FIG. 2D are process cross-sectional views showing the method of manufacturing the semiconductor device of Embodiment 1.

First, in FIG. 2A, the conductive wires 2, the end portions of which are used as inner leads, are provided on the tape carrier 1. Then, the semiconductor chip 5 is joined to the tape carrier 1 such that electrode pads are arranged via the protruding electrodes 6 formed at positions opposing the inner leads for the semiconductor chip 5. Further, the solder resist 3 is formed so as to cover the portion of the conductive wires 2. Here, a polyimide material or the like is generally used as the tape carrier 1, but other resins may be used. As the conductive wires 2, a material whose main component is copper, silver, aluminum, tin, palladium, nickel, gold, or the like, is preferable. And as the protruding electrodes 6, a metal material whose main component is copper, aluminum, tin, palladium, nickel, gold, or the like, is preferable.

Next, in FIG. 2B, the insulating resin 4 is packed into the space between the semiconductor chip 5 and the tape carrier 1, in order to protect the surface of the semiconductor chip 5. This insulating resin 4 is dripped in an appropriate amount to perform molding, with a portion thereof being formed on the side-face portions of the semiconductor chip 5, to form the taper portion 4a. In this Embodiment, after the tape carrier 1 with the conductive wires and the semiconductor chip 5 are joined via the protruding electrodes 6, the insulating resin 4 is packed between the tape carrier 1 and the semiconductor chip 5. As a separate method, by applying the insulating resin 4 in advance, molding can be performed simultaneously when joining the tape carrier 1 having the conductive wires and the semiconductor chip 5.

Next, in FIG. 2C, the resin layer 7 is formed by affixing a sheet-shaped resin layer so as to be in close contact with the tape carrier 1 comprising the solder resist 3, the rear face of the semiconductor chip 5, and the taper portion 4a of the insulating resin 4. Here, as the resin layer 7, it is preferable that an inorganic filler such as silica, a carbon, nickel, or other low-melting point metal filler having conductivity, be used. By using a filler with high thermal conductivity, the thermal conductivity of the resin layer 7 is improved. With regard to the filler packing amount, a larger amount of it results in improved thermal conductivity, but too large amount results in a difficulty in maintaining the shape or other problems, so a packing amount of approximately 20 wt % to 80 wt % is preferable depending on applications. With respect to the thickness of the resin layer 7, a thinner layer thereof improves the thermal conductivity, therefore a thickness of approximately 20 μm to 500 μm is preferable. With respect to uniformity of thickness, a uniform overall thickness is satisfactory, but because the largest amount of heat is dissipated from the rear face of the semiconductor chip, it is preferable that the thickness of the semiconductor chip rear-face portion be reduced. Further, in this Embodiment, the sheet-shaped resin layer 7 is affixed; but by applying a resin in paste form, formation in a similar shape is possible. It is preferable that the resin layer 7 be adhesive.

Further, it is preferable that the resin layer 7 be a thermosetting resin (an epoxy resin or the like). Also, if a thermoplastic resin is used, then by applying heat to allow the metal layer 9 to be in close contact, adhesion with improved closeness of contact becomes possible.

Next, as shown in FIG. 2D, the metal layer 9, having the depression 8 with a shape similar to those of the semiconductor chip 5 and the taper portion 4a of the insulating resin 4, is affixed to the resin layer 7. It is preferable that the depression 8 of the metal layer 9 be of a shape closely corresponding to the shape of the taper portion 4a of the insulating resin 4. Further, heating may be performed, when or after affixing the metal layer 9. By applying heat, the adhesion is improved.

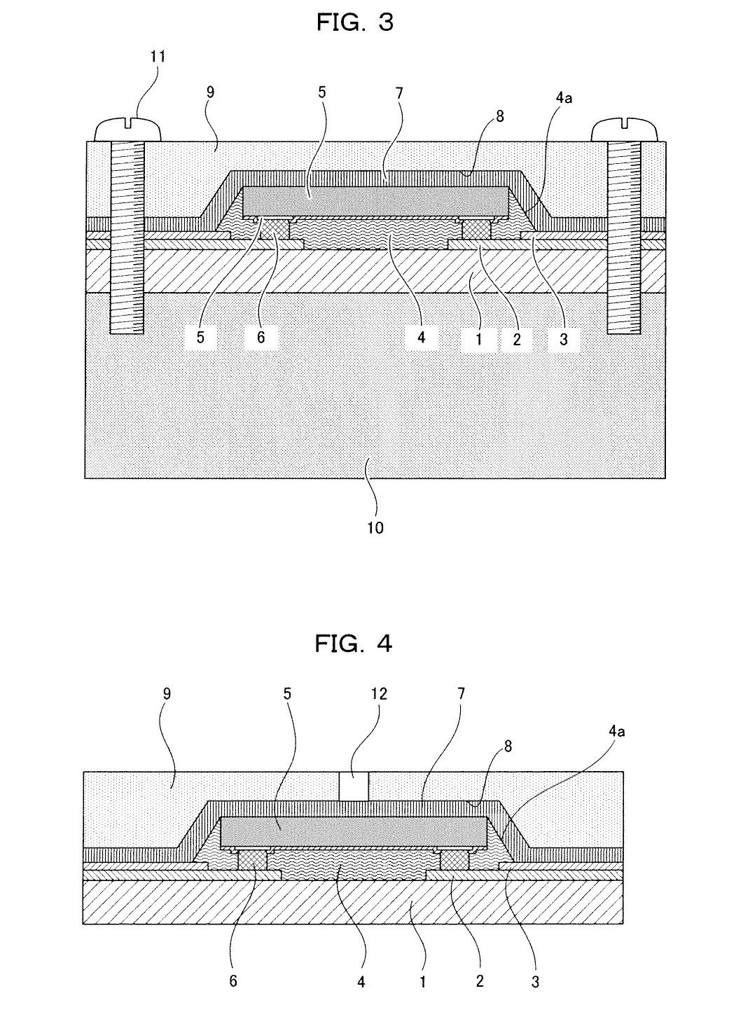

FIG. 3 is a cross-sectional view showing the structure of the mounted semiconductor device in Embodiment 1, and shows an example of a mounted member in which a semiconductor device of the present invention is connected to a housing of a product.

As shown in FIG. 3, in the mounted member of the semiconductor device in Embodiment 1, holes are formed so as to penetrate the metal layer 9, resin layer 7, and tape carrier 1 of a portion of the semiconductor device, and moreover screws 11 pass through the holes to fix the semiconductor device to a housing 10 of the product. Here, in cases where the conductive wires 2 on the tape carrier 1 and the screws 11 are connected, heat from the conductive wires 2 is transmitted from the screws 11 to the housing 10, whereby the advantageous result of still greater heat dissipation is obtained. And, in cases where the conductive wires 2 are connected to GND potential, because GND potential is electrically stable, the advantageous result of improved electrical characteristics is also obtained.

It is preferable that the housing 10 be of metal. And, it is preferable that the semiconductor device and the housing 10 be in close contact. Here, in order to improve the adhesion, a resin layer may be formed between the semiconductor device and the housing 10. It is preferable that a filler, such as the resin layer described above, or another material which improves heat dissipation characteristics, be added to this resin layer.

Here, the screws 11 are used for fixing in place, but rivets may be used.

Also, the semiconductor device to be mounted can be mounted similarly to semiconductor devices in Embodiment 2 to Embodiment 4, described below.

By means of this configuration, whereas in the prior art heat was dissipated only from the rear face of a semiconductor chip, a metal layer which functions as a heat spreader, a semiconductor chip, and a tape carrier can be fixed in place, the metal layer can be fastened with stability, and with respect to heat dissipation, heat from the semiconductor chip can be effectively dissipated not only from the rear face of the semiconductor chip but from side faces as well, whereby the heat dissipation characteristic can be improved.

### Embodiment 2

FIG. 4 is a cross-sectional view showing the structure of a semiconductor device of Embodiment 2.

In this embodiment, conductive wires 2 are provided on a tape carrier 1 in FIG. 4, and inner leads are formed at the end portions of the tape carrier. Each inner lead is joined to an electrode pad of a semiconductor chip 5, with a protruding electrode 6 intervening. Further, solder resist 3 is formed so as to cover a portion of the conductive wires 2.

Here, an insulating resin 4 to protect the surface of the semiconductor chip 5 is packed between the tape carrier 1 and the semiconductor chip 5. This insulating resin 4 is also formed on a portion of the side-face portions of the semiconductor chip 5, to form a taper portion 4a.

Further, a resin layer 7 is formed, in close contact with the tape carrier 1, the rear face of the semiconductor chip 5, and the taper portion 4a of the insulating resin 4.

Further, a metal layer 9, having a depression 8 corresponding to the shapes of the semiconductor chip 5 and the taper portion 4a of the insulating resin 4, is formed in close contact with the resin layer 7. Here, a hole 12 is formed in the metal layer 9 in a region above the semiconductor chip 5. By means of this hole 12 the surface area of the metal layer 9 increases, and the heat dissipation effect is improved. Here the hole 12 may penetrate the metal layer 9, or may not penetrate. If the hole penetrates, by forming a hole in the resin layer 7 also, in a position corresponding to the hole 12 formed in the metal layer 9, trapping of air when bringing the metal layer 9 into close contact with the semiconductor chip 5 can be prevented. In all cases, only one hole 12, as in FIG. 4, or a plurality of holes may be formed.

By means of this structure, heat can be transmitted efficiently and stably from the rear face and side faces of the semiconductor chip to the metal layer having excellent thermal conductivity.

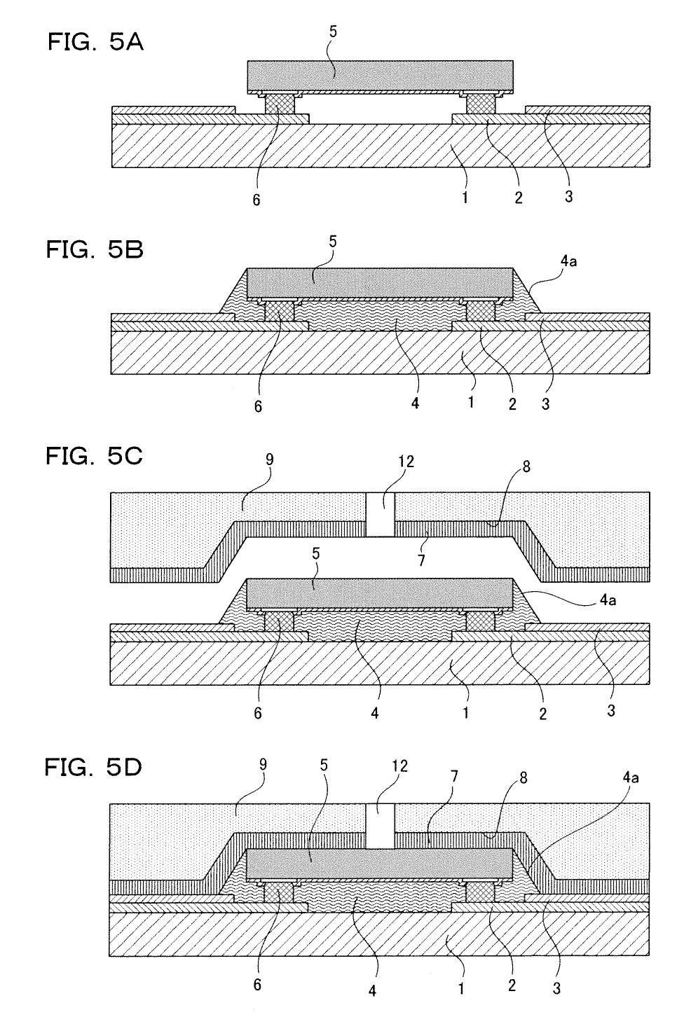

Next, a method of manufacture of the semiconductor device of Embodiment 2 is explained using FIG. 5A to FIG. 5D. FIG. 5A to FIG. 5D are process cross-sectional views showing the method of manufacture of the semiconductor device of Embodiment 2.

In FIG. 5A, the conductive wires 2, the end portions of which are used as inner leads, are provided on the tape carrier 1. Then, the semiconductor chip 5 is joined to the tape carrier 1 such that electrode pads are arranged via the protruding electrodes 6 formed at positions opposing the inner leads for the semiconductor chip 5. Further, the solder resist 3 is formed so as to cover a portion of the conductive wires 2. Here, a polyimide material or similar is generally used as the tape carrier 1, but other resins may be used. As the conductive wires 2, a material whose main component is copper, silver, aluminum, tin, palladium, nickel, gold, or the like, is preferable. And as the protruding electrodes 6, a metal material whose main component is copper, aluminum, tin, palladium, nickel, gold, or the like, is preferable.

Next, in FIG. 5B the insulating resin 4 is packed into the space between the semiconductor chip 5 and the tape carrier 1, in order to protect the surface of the semiconductor chip 5. This insulating resin 4 is dripped in an appropriate amount to perform molding, with a portion thereof being formed on the side-face portions of the semiconductor chip 5, to form the taper portion 4a. In this embodiment, after the tape carrier 1 having the conductive wires and the semiconductor chip 5 are joined via the protruding electrodes 6, the insulating resin 4 is packed between the tape carrier 1 and the semiconductor chip 5. As a separate method, by applying the insulating resin 4 in advance, molding can be performed simultaneously when joining the tape carrier 1 having the conductive wires and the semiconductor chip 5.

Next, in FIG. 5C, by affixing in advance, to the metal layer 9 having the depression 8 with a shape corresponding to those of the semiconductor chip 5 and the taper portion 4a of the insulating resin 4, a sheet-shaped resin layer so as to be in close contact with the tape carrier 1 comprising the solder resist 3, the rear face of the semiconductor chip 5, and the taper portion 4a of the insulating resin 4, the resin layer 7 is formed on the metal layer 9. Here, as the resin layer 7, it is preferable that an inorganic filler such as silica, a carbon, nickel, or other low-melting point metal filler having conductivity, be used. By using a filler with high thermal conductivity, the thermal conductivity of the resin layer 7 is improved. With regard to the filler packing amount, a larger amount thereof results in improved thermal conductivity, but too large amount results in a difficulty in maintaining the shape or other problems, therefore a packing amount of approximately 20 wt % to 80 wt % is preferable depending on applications. With respect to the thickness of the resin layer 7, a thinner layer thereof improves the thermal conductivity, so a thickness of approximately 20 μm to 500 μm is preferable. With respect to uniformity of thickness, a uniform overall thickness is satisfactory, but because the largest amount of heat is dissipated from the rear face of the semiconductor chip, it is preferable that the thickness of the semiconductor chip 5 rear-face portion be reduced. Further, in this embodiment a sheet-shaped resin layer 7 is affixed; but by applying a resin in paste form, formation in a similar shape is possible.

At this time, the metal layer 9 is used which has the hole 12 formed in the region above the semiconductor chip 5. By means of this hole 12 the surface area of the metal layer 9 increases, whereby the heat dissipation effect is improved. And the resin layer 7 which also has a hole 12 in the position corresponding to the hole 12 formed in the metal layer 9 may also be used. By means of this configuration, trapping of air when bringing the metal layer 9 into close contact with the semiconductor chip 5 can be prevented.

Also, it is preferable that a thermoplastic resin be used as the resin layer 7. In this case, by applying heat and bringing the resin layer 7 into close contact with the metal layer 9, adhesion with improved closeness of contact becomes possible.

Next, as shown in FIG. 5D, the metal layer 9, on which is formed the resin layer 7 which has the depression 8 in the shape of the semiconductor chip 5 and the taper portion 4a of the insulating resin 4, is affixed so as to correspond to the taper portion 4a. Here, it is preferable that the resin layer 7 be adhesive. It is preferable that the depression 8 in the metal layer 9 be of a shape corresponding to the shape of the taper portion 4a of the insulating resin 4.

Similarly to Embodiment 1, a semiconductor device mounted member can be formed by connecting the semiconductor device of Embodiment 2 to a housing.

By means of this configuration, whereas in the prior art heat was dissipated only from the rear face of a semiconductor chip, a metal layer which functions as a heat spreader, a semiconductor chip, and a tape carrier can be fixed in place, the metal layer can be fastened with stability, and with respect to heat dissipation, heat from the semiconductor chip can be effectively dissipated not only from the rear face of the semiconductor chip but from side faces as well, so that the heat dissipation characteristic can be improved.

FIG. 7 is a cross-sectional view showing the structure of another semiconductor device of Embodiment 2. In this structure, a cutout 21 is formed on the side of the metal layer 9 opposite the depression 8. This cutout may stop in the center of the metal layer 9, or may reach as far as the depression 8. Further, a plurality of cutouts 21 may be formed in the entire surface of the metal layer 9. And, both holes 12 and cutouts 21 may be formed.

By this means, the surface area of the metal layer 9 is increased, and heat dissipation can be improved. Further, when the cutouts reach as far as the depression 8, degradation of adhesion due to trapping of air, which tends to occur in the resin layer 7, at the time of adhesion of the semiconductor chip and the metal layer can be prevented.

### Embodiment 3

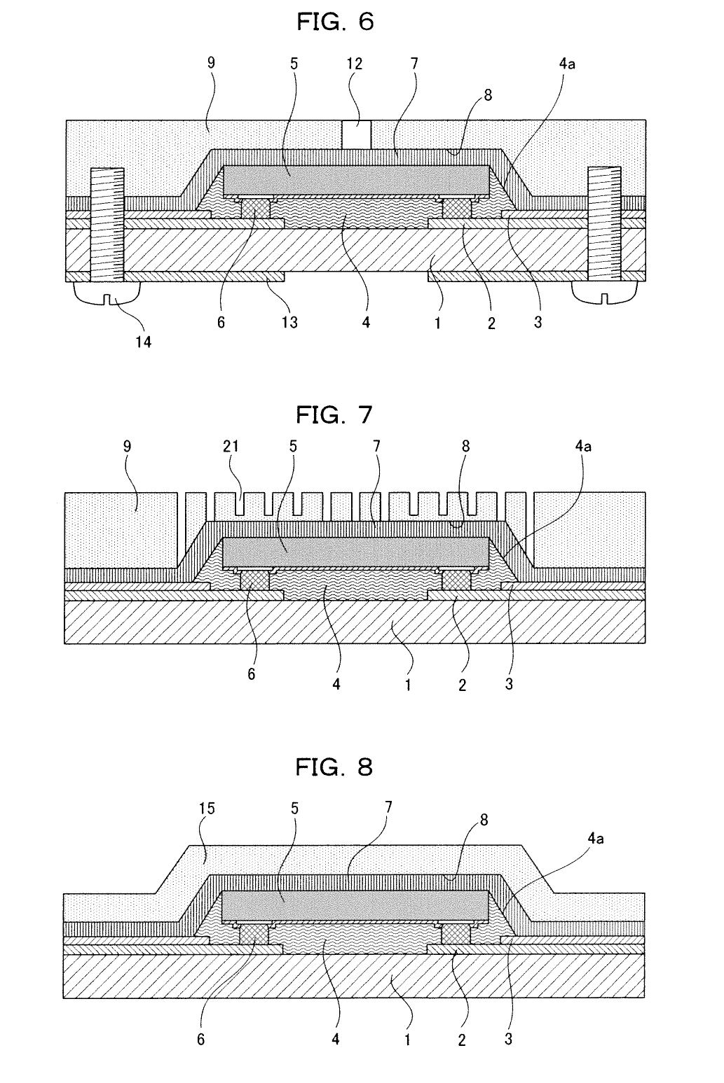

FIG. 6 is a cross-sectional view showing the structure of a semiconductor device of Embodiment 3.

In this embodiment, as shown in FIG. 6, a separate metal layer 13 is provided on the rear face of the tape carrier 1 of the semiconductor device of Embodiment 1 or Embodiment 2. Further, screws 14 penetrate the metal layer 13 on the rear face of the tape carrier, the tape carrier 1, and a resin layer 7 and are fixed to a metal layer 9. Here, the screws 14 are used, but rivets may be used as well. Also, it is preferable that the screws 14 be close to a semiconductor chip 5, and preferably be formed within a distance of 50 mm therefrom. By this means, separation of the resin layer 7 occurring due to stress resulting from a difference in thermal expansion coefficients of the resin layer 7 and metal layer 9 when heat is generated by the semiconductor chip 5 can be prevented. Further, heat transmitted through the screws 14 in this configuration is also transmitted to the rear face of the tape carrier, whereby the advantageous result of dissipation of heat transmitted to the metal layer 13 on the rear face of the tape carrier 1 is enhanced. In this embodiment, a separate metal layer 13 is formed on the rear face of the tape carrier 1, but the screws 14 can be used for fixing to the metal layer 9, without forming a metal layer 13.

Further, when the screws 14 are connected to the GND potential of the conductive wires 2, the metal layer 13 is connected to the GND potential, whereby the shield effect can be improved.

### Embodiment 4

FIG. 8 is a cross-sectional view showing the structure of a semiconductor device of Embodiment 4.

In FIG. 8, conductive wires 2 are provided on a tape carrier 1, and the end portions of the tape carrier form inner leads. Each inner lead is joined with an electrode pad of a semiconductor chip 5 via a protruding electrode 6. And, solder resist 3 is formed so as to cover a portion of the conductive wires 2.

An insulating resin 4 is packed between the tape carrier 1 and the semiconductor chip 5 in order to protect the surface of the semiconductor chip 5. This insulating resin 4 is also formed on a portion of the side-face portions of the semiconductor chip 5, to form a taper portion 4a.

Further, a resin layer 7 similar to those of Embodiment 1 and others is formed on the tape carrier 1, in close contact with the rear face of the semiconductor chip 5 and with the taper portion 4a of the insulating resin 4. Here, as the resin layer 7, it is preferable that an inorganic filler such as silica, a carbon, nickel, or other low-melting point metal filler having conductivity, be used. Further, it is preferable that the resin layer 7 be a thermosetting resin (an epoxy resin or the like). Also, if a thermoplastic resin is used, then by applying heat to allow the metal layer 9 to be in close contact, adhesion with improved closeness of contact becomes possible.

Further, a sheet-shaped metal layer 15 is formed on the resin layer 7 in close contact, with the shape corresponding to the resin 7.

By means of this structure, heat can be transmitted efficiently and stably from the rear face and side faces of the semiconductor chip to the metal layer having excellent thermal conductivity.

By means of this configuration, a sheet-shaped metal layer can be used, so that an inexpensive semiconductor device can be provided.

### Embodiment 5

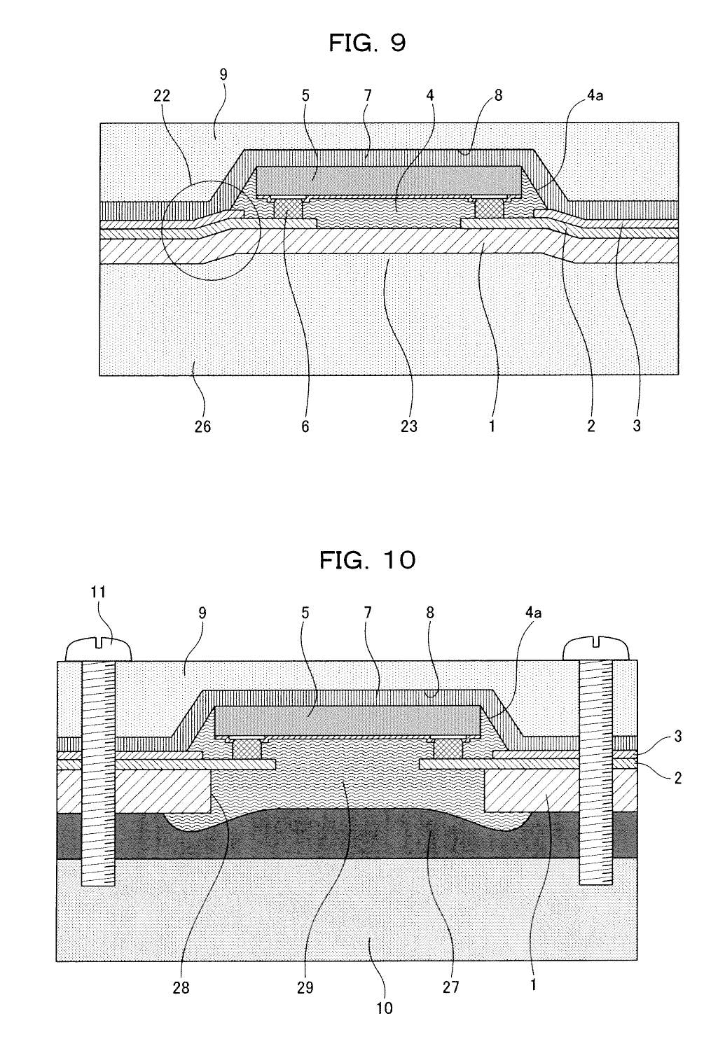

FIG. 9 is a cross-sectional view showing the structure of a semiconductor device of Embodiment 5.

In FIG. 9, conductive wires 2 are provided on a tape carrier 1, and the end portions thereof form inner leads. Each inner lead is joined with an electrode pad of a semiconductor chip 5 via a protruding electrode 6. And, solder resist 3 is formed so as to cover a portion of the conductive wires 2.

Here, an insulating resin 4 is packed between the tape carrier 1 and the semiconductor chip 5 to protect the surface of the semiconductor chip 5. This insulating resin 4 is also formed on a portion of the side-face portions of the semiconductor chip 5, to form a taper portion 4a.

Further, a resin layer 7 similar to those of Embodiment 1 and others is formed on the tape carrier 1, in close contact with the rear face of the semiconductor chip 5 and with the taper portion 4a of the insulating resin 4. Here, as the resin layer 7, it is preferable that an inorganic filler such as silica, a carbon, nickel, or other low-melting point metal filler having conductivity, be used. Further, it is preferable that the resin layer 7 be a thermosetting resin (an epoxy resin or the like). Also, if a thermoplastic resin is used, then by applying heat to allow a metal layer 9 to be in close contact, adhesion with improved closeness of contact becomes possible.

Further, on the resin layer 7, the metal layer 9 is formed having a depression 8 with the shape corresponding to those of the semiconductor chip 5 and to the taper portion 4a of the insulating resin 4.

Further, a metal layer 26 is formed on the rear-face side of the tape carrier 1 opposite the side on which the conductive wires 2 are formed; a protruding portion 23 is formed in this metal layer 26 in a region opposing the semiconductor chip 5. By this means a force pressing the semiconductor chip 5 upward is generated, deformation 22 of the tape carrier is caused, and the semiconductor chip 5 can be brought close to the metal layer 9. By this means, the closeness of contact of the semiconductor chip 5 and the resin layer 7 is improved, whereby the heat dissipation characteristic can be improved.

Here, the metal layer 26 can also be formed on the rear face of the tape carrier 1 without forming the protruding portion 23, thereby improving the characteristics of the heat dissipation from the surface side of the semiconductor chip 5.

Further, similarly to Embodiment 2, one or a plurality of holes or cutouts may be formed in the metal layer 9, in a region above the semiconductor chip 5.

Further, similarly to Embodiment 3, screws may penetrate the metal layer 26 on the rear face of the tape carrier, the tape carrier 1, and the resin layer 7, to be fixed in the metal layer 9. Here screws are used, but rivets may also be used.

Further, similarly to Embodiment 1, a hole can be formed so as to penetrate a portion of the metal layer 9, the resin layer 7, the tape carrier 1, and the metal layer 26 of the semiconductor device, and moreover a screw passing through this hole can be used to fix the semiconductor device to a housing of a product, to form a semiconductor device mounted member.

### Embodiment 6

FIG. 10 is a cross-sectional view showing the structure of a semiconductor device of Embodiment 6.

In FIG. 10, conductive wires 2 are provided on a tape carrier 1, and the end portions thereof form inner leads; a hole portion 28 is formed in the region of the inner lead portion of the tape carrier 1 opposing a semiconductor chip 5. Each inner lead is joined with an electrode pad of the semiconductor chip 5 via a protruding electrode 6. And, solder resist 3 is formed so as to cover a portion of the conductive wires 2.

Here, an insulating resin 29 is packed in the hole portion 28 of the tape carrier 1 and covers the surface of the semiconductor chip 5 to protect the surface of the semiconductor chip 5. This insulating resin 29 is also formed on a portion of the side-face portions of the semiconductor chip 5, to form a taper portion 4a.

Further, a resin layer 7 is formed on the tape carrier 1, in close contact with the rear face of the semiconductor chip 5 and with the taper portion 4a of the insulating resin 29. Here, as the resin layer 7, it is preferable that an inorganic filler such as silica, a carbon, nickel, or other low-melting point metal filler having conductivity, be used. Further, it is preferable that the resin layer 7 be a thermosetting resin (an epoxy resin or the like). Also, if a thermoplastic resin is used, then by applying heat to allow the metal layer 9 to be in close contact, adhesion with improved closeness of contact becomes possible.

Further, a metal layer 9, having a depression 8 corresponding to the shapes of the semiconductor chip 5 and the taper portion 4a of the insulating resin 29, is formed in close contact with the resin layer 7. It is preferable that the depression 8 of the metal layer 9 correspond to the shape of the taper portion 4a of the insulating resin 4. Further, heating may be performed when bringing the two into close contact. Further, heating may be performed after bringing them into close contact. By applying heat, closeness of contact is improved. Here, similarly to Embodiment 2, one or a plurality of holes or cutouts may be formed in the metal layer 9 in the region above the semiconductor chip 5.

Further, a resin layer 27 can be formed below the insulating resin 29 and tape carrier 1.

Further, a hole can be formed penetrating the metal layer 9, resin layer 7, tape carrier 1, resin layer 27, and insulating resin 29, and a screw 11 passing through this hole can be fixed to a housing 10 of a product, to fix the semiconductor device in place.

Here, the screws 11 were used for fixing in place, but rivets may be used as well.

By means of this configuration, whereas in the prior art heat dissipation was only from the rear face of a semiconductor chip, a metal layer functioning as a heat spreader, a semiconductor chip and a tape carrier can be fixed in place, the metal layer can be fastened with stability, and with respect to heat dissipation, heat from the semiconductor chip can be effectively dissipated not only from the rear face of the semiconductor chip but from side faces as well, whereby the heat dissipation characteristic can be improved.

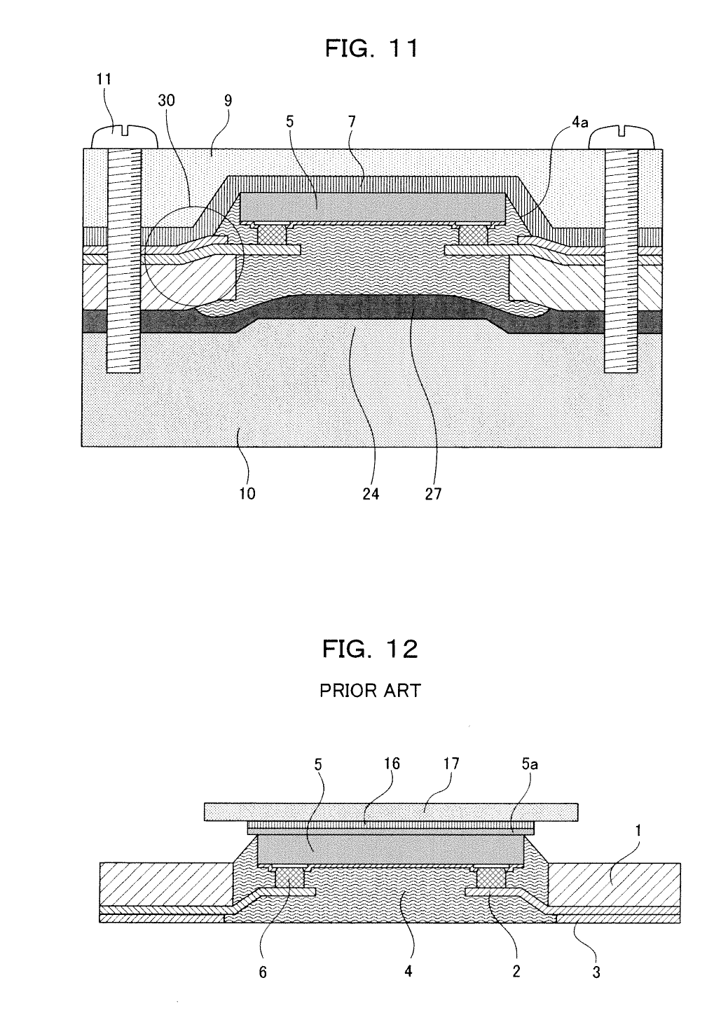

FIG. 11 is a cross-sectional view showing another structure of the mounted semiconductor device in Embodiment 6, and is a cross-sectional view showing a mounting structure in a case in which a protruding portion 24 is provided on the surface of the housing in the above semiconductor device mounted member.

Here, the protruding portion 24 is formed in the region of the housing 10 corresponding to the semiconductor chip 5. By this means, a force is generated to push the semiconductor chip 5 upwards, causing the tape carrier to be deformed, and the semiconductor chip 5 can be brought closer to the metal layer 9. Further, by fastening the device in place using the screws 11, the semiconductor chip 5 can be brought closer to the metal layer 9 with stability. As a result, the heat dissipation characteristic can be improved. Here, the protruding portion 24 is formed on the housing 10; however, a configuration may be employed in which a protruding portion 23 is formed on the metal layer 26 instead of the housing, as in Embodiment 5.

What is claimed is:

1. A semiconductor device, in which a semiconductor chip is mounted on a tape carrier, comprising:
an insulating resin, packed into a gap between the tape carrier and the semiconductor chip, and forming a taper portion on side faces;
a resin layer, formed so as to be in contact with a rear face of the semiconductor chip and with at least a portion of the tape carrier as well as with the taper portion, and having higher thermal conductivity than the insulating resin; and
a metal layer, comprising a depression with a shape corresponding to the semiconductor chip and the insulating resin layer on the taper portion, and formed so as to be in close contact with the resin layer.

2. A semiconductor device, in which a semiconductor chip is mounted on a tape carrier, comprising:
an insulating resin packed so as to cover a surface of the semiconductor chip, and forming a taper portion on side faces, with a hole formed in the tape carrier in a region opposing the semiconductor chip;
a resin layer, formed so as to be in contact with a rear face of the semiconductor chip and with at least a portion of the tape carrier as well as with the taper portion, and having higher thermal conductivity than the insulating resin; and
a metal layer, comprising a depression with a shape corresponding to the semiconductor chip and the insulating resin layer on the taper portion, and formed so as to be in close contact with the resin layer.

3. The semiconductor device according to claim 1, wherein the metal layer is a sheet-shaped metal layer formed corresponding to a shape of the resin layer.

4. The semiconductor device according to claim 1, wherein one or a plurality of holes are formed in a portion of the metal layer in a region above the semiconductor chip.

5. The semiconductor device according to claim 1, wherein the metal layer has a cutout in a surface on a side opposite a side in which the depression is formed.

6. The semiconductor device according to claim 1, further comprising a second metal layer on a rear face of the tape carrier.

7. The semiconductor device according to claim 6, wherein a region of the second metal layer opposing the semiconductor chip protrudes in a direction of the tape carrier.

8. The semiconductor device according to claim 2, further comprising a second resin layer on a rear face of the tape carrier.

9. The semiconductor device according to claim 8, further comprising a housing having a protruding portion on a rear face of the second resin layer, a region of the housing opposing the semiconductor chip protruding in a direction of the tape carrier.

10. The semiconductor device according to claim 6, wherein the metal layer, the tape carrier, and the second metal layer are fixed in place with a screw or rivet.

11. The semiconductor device according to claim 8, wherein the metal layer, the tape carrier, and the second resin layer are fixed in place with a screw or rivet.

12. The semiconductor device according to claim 1, wherein a screw or rivet penetrates the tape carrier and the metal layer.

13. The semiconductor device according to claim 1, wherein a third metal layer is formed on a rear face of the tape carrier, and a screw or rivet penetrates the third metal layer, the tape carrier, and the metal layer.

14. The semiconductor device according to claim 10, wherein the screw or rivet is provided within 50 mm from the semiconductor chip.

15. The semiconductor device according to claim 1, wherein a conductive filler is intermixed in the resin layer.

16. The semiconductor device according to claim 1, wherein the resin layer has a low-melting point metal filler.

17. The semiconductor device according to claim 1, wherein the resin layer comprises a thermoplastic resin.

18. A method of manufacturing a semiconductor device, comprising the steps of:
mounting a semiconductor chip on a tape carrier, and positioning a plurality of electrode pads formed on a surface of the semiconductor chip and a plurality of conductive wires formed on the tape carrier to correspond to the electrode pads, and connecting the plurality of electrode pads to the plurality of conductive wires via protruding electrodes;
packing a gap between the tape carrier and the semiconductor chip with an insulating resin, so as to form a taper portion on side faces;
forming a resin layer, having higher thermal conductivity than the insulating resin layer, so as to be in contact with a rear face of the semiconductor chip and at least a portion of the tape carrier as well as the taper portion; and
fastening a metal layer having a depression with a shape corresponding to the semiconductor chip and to the insulating resin layer on the taper portion, so as to be in close contact with the resin layer.

19. The method of manufacturing a semiconductor device according to claim 18, wherein one or a plurality of holes are formed in a portion of the metal layer above the semiconductor chip.

20. The method of manufacturing a semiconductor device according to claim 18, wherein, after the metal layer fastening step, heating is performed to allow the metal layer to be in closer contact.
